(19) United States
(12) Patent Application Publication
(10) Pub. No.: US 2007/0134911 A1
(43) Pub. Date: Jun. 14, 2007

(54) Dual damascene process and method for forming a copper interconnection layer using same

(75) Inventor: Jae-Hyun Kang, Seoul (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Dongbu Electronics Co., Ltd.

(21) Appl. No.: 11/634,308

(22) Filed: Dec. 6, 2006

(30) Foreign Application Priority Data
Dec. 14, 2005 (KR) 10-2005-0123367

(51) Int. Cl. H01L 21/4763

(52) U.S. Cl. 438/624

(57) ABSTRACT

A method for forming a copper interconnection using a dual damascene process includes forming a second insulating layer on a first insulating layer, the first insulating layer including a lower metal interconnection layer formed therein; forming a photoresist film pattern on the second insulating layer; forming a dry film resist film pattern on the photoresist film pattern; forming a via hole and a trench in the second insulator layer to expose a portion of the lower metal interconnection layer by etching the second insulating layer using the dry film resist film pattern and the photoresist film pattern as an etching mask; removing the DFR film pattern and the photoresist film pattern; forming a copper layer to fill the via hole and the trench; and planarizing the copper layer to form a copper interconnection layer. Planarizing the copper layer is performed using a chemical mechanical polishing method.

### RELATED APPLICATION

This application is based upon and claims the benefit of priority to Korean Application No. 10-2005-0123367, filed on Dec. 14, 2005, the entire contents of which are incorporated herein by reference.

### TECHNICAL FIELD

The present invention relates to a method for forming a metal interconnection layer, and more particularly to a simplified dual damascene process and a method for forming a copper interconnection layer using the simplified dual damascence process.

### BACLGROUND

Recently, copper has been used more frequently than aluminum as a material for forming a metal interconnection layer for a semiconductor device. Particularly, for fabricating a logic device, a copper interconnection layer is more favorable over an aluminum interconnection layer, because copper has a lower RC (resistance-capacitance) delay and a higher conductivity. However, since it is difficult to etch copper during a process of forming a copper interconnection, a damascene process (e.g., dual damascene process) is generally used in forming a copper interconnection layer to overcome such a problem.

FIGS. 1 to 5 illustrate cross-sectional views for explaining a conventional dual damascene process and a method for forming a copper interconnection layer using the conventional dual damascene process.

First, as shown in FIG. 1, a second insulating layer 130 is formed on a first insulating layer 110 including a lower metal interconnection layer 120. First insulating layer 110 is formed on a semiconductor substrate 100. Then, a photoresist film pattern 140 is formed on second insulating layer 130, photoresist film pattern 140 being patterned to expose a part of second insulating layer 130.

Thereafter, as shown in FIG. 2, a via hole 152 is formed by etching the part of second insulating layer 130 that is exposed through an etching mask (i.e., photoresist film pattern 140 as shown in FIG. 1). Photoresist film pattern 140 used as the etching mask is removed after via hole 152 is formed. A resist film 160 is then formed on an entire surface of the resultant substrate structure, so as to fill via hole 152.

Next, as shown in FIG. 3, resist film 160 is partially removed through an ashing process to expose an upper surface of second insulating layer 130 while also forming a recess in an upper part of the resist film remaining in via hole 152. A photoresist film pattern 170 is formed on second insulating layer 130.

As shown in FIG. 4, second insulating layer 130 is etched using photoresist film pattern 170 (see FIG. 3) as an etching mask to expose via hole 152 and form a trench 154 in an upper part of second insulating layer 130.

Then, as shown in FIG. 5, a copper layer is formed on the entire surface of the resultant substrate structure to fill via hole 152 and trench 154. Finally, the copper layer is planarized to form a copper interconnection layer 180 having a dual damascene structure.

In the above-described dual damascene process for forming a copper interconnection layer, as shown in FIGS. 2 and 3, a Novalac process for filling resist film 160 in the via hole 152 is performed to uniformly coat photoresist film pattern 170 thereon. However, performing the Novalac process complicates the whole process and may cause defects during a subsequent process for forming trench 154.

### SUMMARY

Consistent with the present invention, there is provided a dual damascene process without a Novalac process.

Consistent with the present invention, there is also provided a method for forming a copper interconnection layer using the dual damascene process.

In accordance with one embodiment of the present invention, there is provided a dual damascene process including the steps of: forming a second insulating layer on a first insulating layer, the first insulating layer including a lower metal interconnection layer formed therein; forming a photoresist film pattern on the second insulating layer; forming a dry film resist film pattern on the photoresist film pattern; and forming a via hole and a trench in the second insulator layer to expose a portion of the lower metal interconnection layer by etching the second insulating layer using the dry film resist film pattern and the photoresist film pattern as an etching mask.

In accordance with another embodiment of the present invention, there is provided a method for forming a copper interconnection using a dual damascene process, the method including the steps of: forming a second insulating layer on a first insulating layer, the first insulating layer including a lower metal interconnection layer formed therein; forming a photoresist film pattern on the second insulating layer; forming a dry film resist film pattern on the photoresist film pattern; forming a via hole and a trench in the second insulator layer to expose a portion of the lower metal interconnection layer by etching the second insulating layer using the dry film resist film pattern and the photoresist film pattern as an etching mask; removing the DFR film pattern and the photoresist film pattern; forming a copper layer to fill the via hole and the trench; and planarizing the copper layer to form a copper interconnection layer.

### BRIEF DESCRIPTION OF THE DRAWINGS

The features of the present invention will become apparent from the following description of preferred embodiments given in conjunction with the accompanying drawings, in which:

FIGS. 1 to 5 illustrate cross-sectional views for explaining a conventional dual damascene process, and a method for forming a copper interconnection layer using the conventional dual damascene process; and

FIGS. 6 to 11 illustrate cross-sectional views for explaining a dual damascene process in accordance with a preferred embodiment of the present invention, and a method for forming a copper interconnection layer using the dual damascene process.

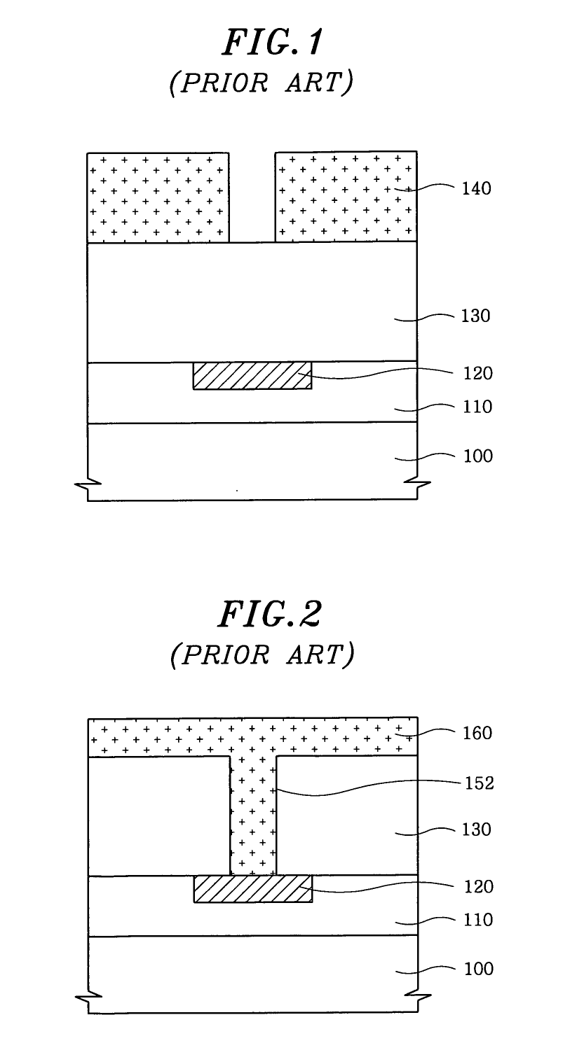

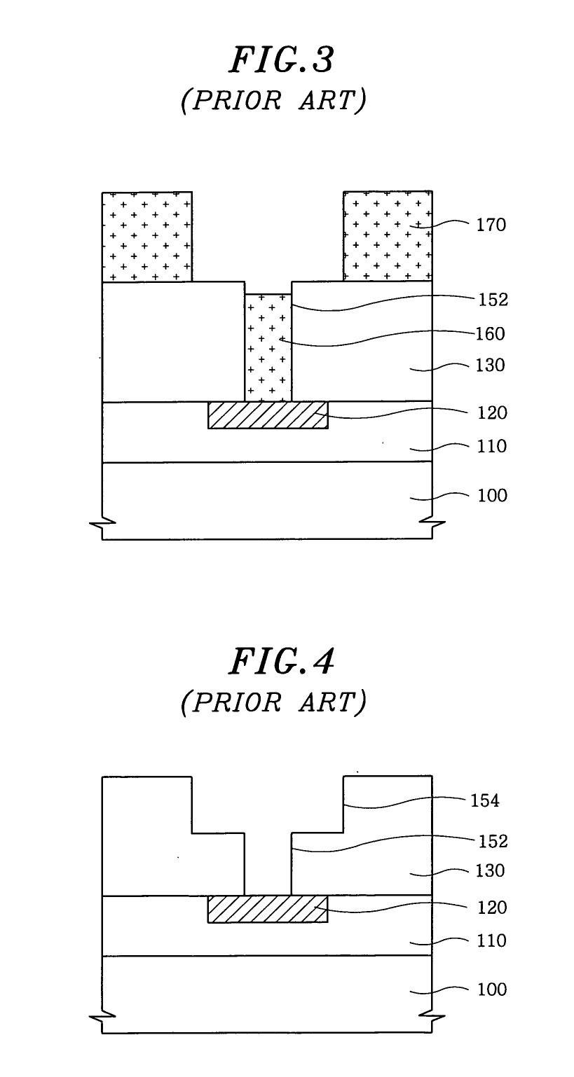

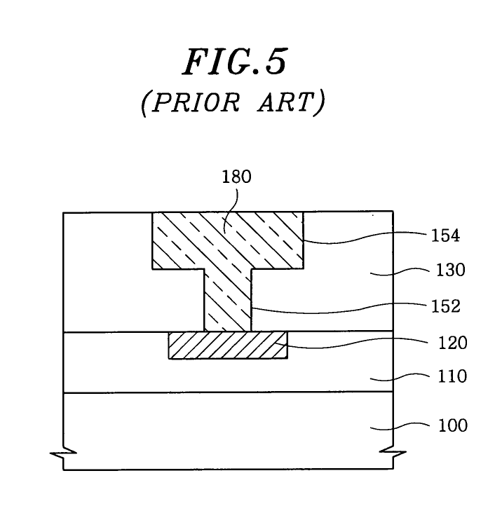

### DETAILED DESCRIPTION

In the following, various embodiments of the present invention will be described in detail with reference to the accompanying drawings.

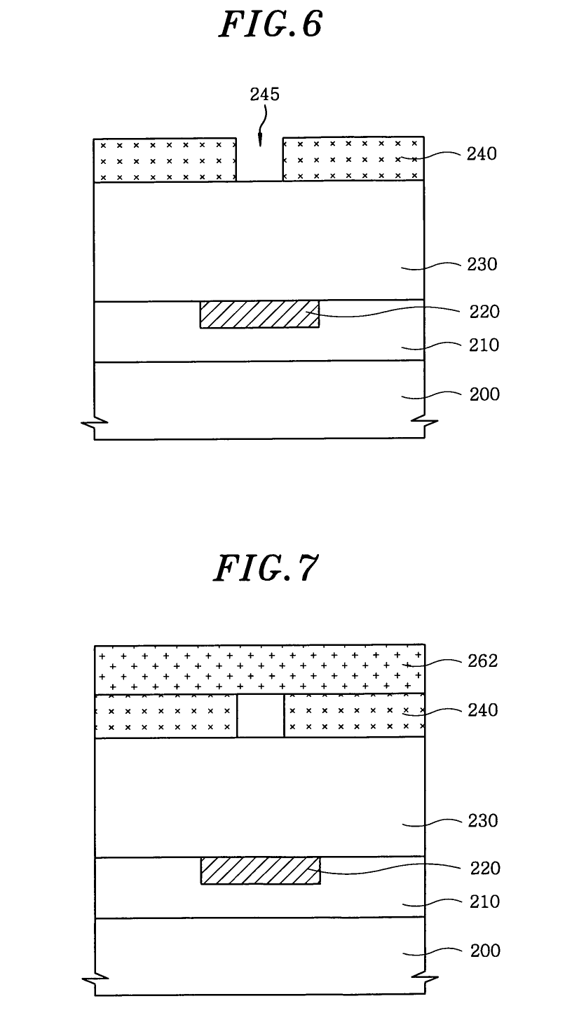

FIGS. 6 to 11 illustrate cross-sectional views for explaining a dual damascene process consistent with an embodiment of the present invention, and a method for forming a copper interconnection layer using the dual damascene process.

Referring to FIG. 6, a second insulating layer 230 is formed on a first insulating layer 210, which includes a lower metal interconnection layer 220, first insulating layer 210 being formed on a semiconductor substrate 200. Although not shown in the drawing, one or more devices may be formed between semiconductor substrate 200 and first insulating layer 210. Also, a plurality of metal interconnection layers may be formed under lower metal interconnection layer 220. Subsequently, a photoresist film pattern 240 is formed on second insulating layer 230. Photoresist film pattern 240 is provided with an opening 245, through which a part of a surface of second insulating layer 230 is exposed. The width of opening 245 is set to be substantially equal to that of a via hole to be formed later.

Referring to FIG. 7, a dry film resist (DFR) film 262 is coated on photoresist film pattern 240. DFR film 262 may be formed using a spin coating method. Alternatively, DFR film 262 may be formed using a taping method. In contrast to photoresist film pattern 240, which is formed by using a solvent, the DFR film 262, in this particular embodiment, is formed by being pressed at a certain pressure without using any solvent. Accordingly, during a process for forming DRF film 262, the lower layer such as photoresist film pattern 240 is not damaged and maintains its characteristics.

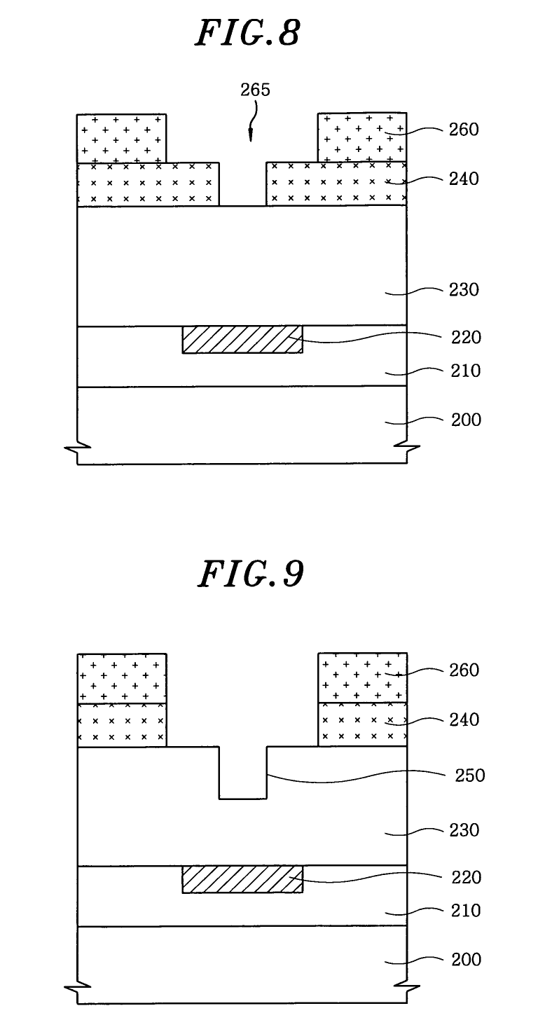

Referring to FIG. 8, DFR film 262 (see FIG. 7) is patterned so that a DFR film pattern 260 is formed for subsequently forming a trench. DFR film pattern 260 is provided with an opening 265 to expose the opening of photoresist film pattern 240, and an area around the opening of photoresist film pattern 204.

Referring to FIG. 9, an etching process is performed using photoresist film pattern 240 and DFR film pattern 260 as an etching mask. Such etching process may be performed using a reactive ion etching (RIE) method. As the etching process proceeds, a recess 250 having a certain depth is formed at a part of second insulating layer 230 that is exposed through the opening of photoresist film pattern 240, while a part of photoresist film pattern 240 exposed through DFR pattern 260 is removed.

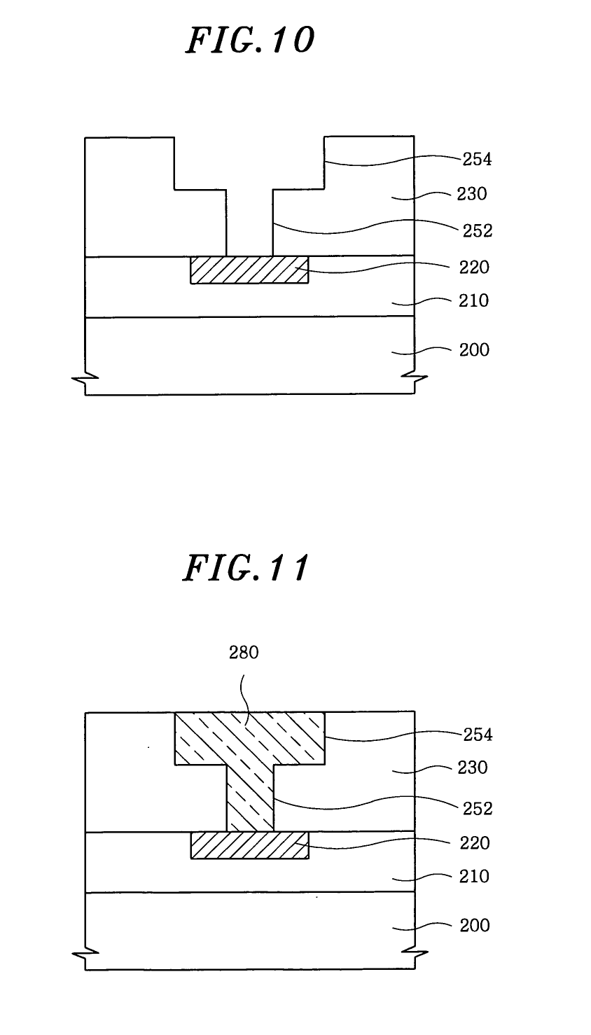

Referring to FIG. 10, by etching subsequently the substrate structure shown in FIG. 9, a via hole 252 is formed in a lower part of second insulating layer 230, through which lower metal interconnection layer 220 is exposed. In an upper part of second insulating layer 230, a trench 254 having a larger width than that of via hole 252 is formed. After forming via hole 252 and trench 254, photoresist film pattern 240 (see FIG. 9) and DFR film pattern 260 (see FIG. 9) are removed.

Referring to FIG. 11, a copper layer is formed on an entire surface of the resulting substrate structure shown in FIG. 10 to fill via hole 252 and trench 254. Thereafter, the copper layer is planarized to form a copper interconnection layer 280 having a dual damascene structure. The planarization of the copper layer may be performed using, e.g., a chemical mechanical polishing (CMP) method.

According to the above-described embodiments for forming a copper interconnection layer using a dual damascene process, an etching process for forming a trench is performed using a DFR film pattern without using a Novalac process nor an ashing process. As such, the dual damascene process for forming a copper interconnection layer is simplified.

While the invention has been shown and described with respect to the preferred embodiments, it will be understood by those skilled in the art that various changes and modifications may be made without departing from the spirit and scope of the invention as defined in the following claims.

What is claimed is:

1. A method for forming an interconnection layer using a dual damascene process, the method comprising the steps of:
forming a second insulating layer on a first insulating layer, the first insulating layer including a lower metal interconnection layer formed therein;
forming a photoresist film pattern on the second insulating layer;
forming a dry film resist film pattern on the photoresist film pattern; and
forming a via hole and a trench in the second insulator layer to expose a portion of the lower metal interconnection layer by etching the second insulating layer using the dry film resist film pattern and the photoresist film pattern as an etching mask.

2. The method of claim 1, wherein the step of forming the dry film resist film pattern includes:
coating a dry film resist film on the photoresist film pattern; and
patterning the dry film resist film to form the dry film resist film pattern exposing an opening of the photoresist film pattern and an area around the opening.

3. The method of claim 1, wherein the trench is wider than the via hole.

4. A method for forming a copper interconnection using a dual damascene process, the method comprising the steps of:
forming a second insulating layer on a first insulating layer, the first insulating layer including a lower metal interconnection layer formed therein;
forming a photoresist film pattern on the second insulating layer;
forming a dry film resist (DFR) film pattern on the photoresist film pattern;
forming a via hole and a trench in the second insulator layer to expose a portion of the lower metal interconnection layer by etching the second insulating layer using the dry film resist film pattern and the photoresist film pattern as an etching mask;
removing the DFR film pattern and the photoresist film pattern;
forming a copper layer to fill the via hole and the trench; and
planarizing the copper layer to form a copper interconnection layer.

5. The method of claim 4, wherein the step of planarizing the copper layer is performed using a chemical mechanical polishing method.

6. The method of claim 4, wherein the via hole is wider than the trench.
